(19) United States
(12) Patent Application Publication
(10) Pub. No.: US 2026/0168100 A1
(43) Pub. Date: Jun. 18, 2026

(54) SUSCEPTOR LEVELING SYSTEM

(71) Applicant: ASM IP Holding B.V., Almere (NL)

(72) Inventor: Leonard Rodriguez, Phoenix, AZ (US)

(21) Appl. No.: 19/419,368

(22) Filed: Dec. 15, 2025

Related U.S. Application Data
(60) Provisional application No. 63/735,418, filed on Dec. 18, 2024.

(51) Int. Cl. C23C 16/458; C23C 14/50

(52) U.S. Cl. CPC C23C 16/4583; C23C 14/50

(57) ABSTRACT

Apparatus and systems suitable for leveling a susceptor are disclosed. An exemplary susceptor leveling assembly comprises a susceptor leveler plate and a first positioning assembly, wherein the first positioning assembly comprises a first positioning device and a first leveling mechanism. An exemplary apparatus includes a pedestal and a susceptor leveling assembly. An exemplary reactor system includes a susceptor, a pedestal, and a susceptor leveling assembly.

### CROSS-REFERENCE TO RELATED APPLICATIONS

This application is a nonprovisional of, and claims priority to and the benefit of, U.S. Provisional Patent Application No. 63/735,418 , filed Dec. 18, 2024 and entitled “SUSCEPTOR LEVELING SYSTEM,” which is hereby incorporated by reference herein.

### FIELD OF INVENTION

The present disclosure generally relates to systems used in the formation of electronic devices. More particularly, the disclosure relates to systems suitable for leveling susceptors before and after substrate processing.

### BACKGROUND OF THE DISCLOSURE

Gas-phase reactors, such as chemical vapor deposition (CVD) reactors, atomic layer deposition (ALD) reactors and the like, can be used for a variety of applications, including depositing materials to form films on substrates. For example, gas-phase reactors can be used to deposit layers on a substrate to form devices, such as semiconductor devices, flat panel display devices, photovoltaic devices, microelectromechanical systems (MEMS), and the like.

In some applications, the reactor comprises one or more susceptors configured to hold a substrate during a deposition process. It may be desirable to have finetuning control of the reactor, which may require precise leveling of one or more susceptors. Some leveling apparatus use an assembly to level susceptors, which includes positioning devices (e.g., micrometers) directly coupled to a leveling plate. The direct linkage between the positioning device and the leveling plate is highly sensitive and prone to errors. Therefore, it is desirable to develop and use a system that will have less error in controlling the leveling of a susceptor.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to improved systems suitable for controlling leveling of a susceptor. While the ways in which various embodiments of the present disclosure address drawbacks of prior systems and methods are discussed in more detail below, in general, various embodiments of the disclosure provide systems that can be used to, for example, control leveling of a susceptor to a greater level of precision and accuracy.

As described in more detail below, in accordance with examples of the disclosure, a susceptor leveling assembly is disclosed. Examples of the disclosure are conveniently described in connection with leveling a susceptor within a reactor. However, unless noted otherwise, examples of the disclosure are not so limited.

In accordance with additional embodiments of the disclosure, a susceptor leveling assembly is provided. An exemplary susceptor leveling assembly includes a susceptor leveler plate and a first positioning assembly, wherein the first positioning assembly comprises a first positioning device configured to move a pedestal in a vertical direction and a first leveling mechanism in contact with the first positioning device and the susceptor leveler plate. In various embodiments, the first positioning assembly is configured to adjust and angle of the susceptor leveler plate in a first direction relative to a first plane.

In accordance with examples of embodiments, the first positioning assembly comprises a second positioning device and a second leveling mechanism in contact with the second positioning device and the susceptor leveler plate. In various embodiments, the second leveling mechanism is configured to adjust an angle of the susceptor leveler plate in a second direction relative to a second plane. In various embodiments, the first positioning device and the second positioning device are coupled to a first adjustment mechanism frame. In various embodiments, at least one of the first positioning device and the second positioning device comprise a micrometer. In various embodiments, the susceptor leveling assembly comprises a controller in communication with the first positioning device and the second positioning device. In accordance with further examples, the controller is configured to control the first positioning device to adjust the angle of the susceptor leveler plate in the first direction and/or the second direction.

In accordance with additional embodiments of the disclosure, an apparatus is provided. An exemplary apparatus includes a pedestal and a susceptor leveling assembly as described herein.

In accordance with additional embodiments of the disclosure, a reactor system is provided. An exemplary reactor system includes a susceptor, a pedestal, and a susceptor leveling assembly as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates an isometric view of an assembly in accordance with exemplary embodiments of the disclosure.

FIG. 2 illustrates a cross-sectional view of a reactor in accordance with exemplary embodiments of the disclosure.

FIG. 3A and FIG. 3B illustrate views of a positioning device in accordance with exemplary embodiments of the disclosure.

FIG. 4A and FIG. 4B illustrate a susceptor leveling assembly in accordance with exemplary embodiments of the disclosure.

FIG. 5A and FIG. 5B illustrate a susceptor leveling assembly in accordance with further exemplary embodiments of the disclosure.

It will be appreciated that elements in the figures are illustrated for simplicity and clarity and have not necessarily been drawn to scale. For example, the dimensions of some of the elements in the figures can be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to assemblies suitable for use in reactor systems. Such assemblies can be used to control the position of, and level, a susceptor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. Further, the substrate can include various features, such as recesses, protrusions, and the like formed within or on at least a portion of a layer of the substrate.

The term “deposition process” as used herein can refer to the introduction of precursors (and/or reactants) into a reaction chamber to deposit or form a layer over a substrate. This can include chemical vapor deposition (“CVD”), atomic layer deposition (“ALD”), CVD/ALD hybrid deposition, plasma enhanced chemical vapor deposition (“PECVD”), plasma enhanced atomic layer deposition (“PEALD”) and PECVD/PEALD hybrid deposition.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by,” “having,” and their equivalents can refer independently to “typically or broadly comprising,” “comprising,” “consisting essentially of,” or “consisting of” in some embodiments. In this disclosure, any defined meanings do not necessarily exclude ordinary and customary meanings in some embodiments. Further, the term “about” can refer to +/−20, 10, 5, 2, 1 or 0.5 percent of a value, and any value noted herein can be +/−20, 10, 5, 2, 1 or 0.5 percent of the value.

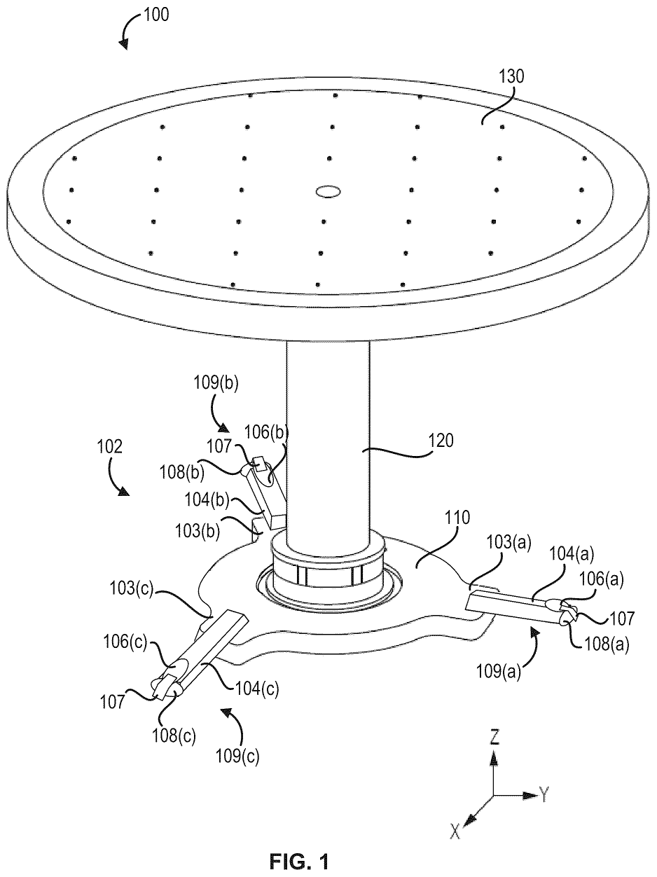

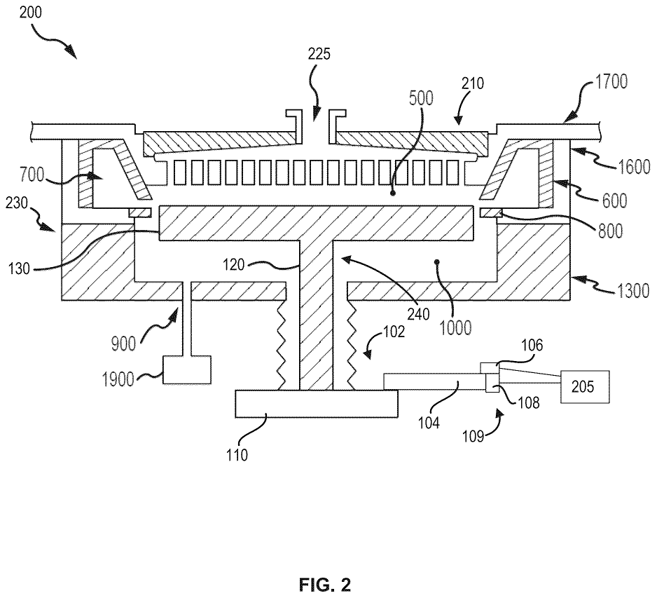

Turning now to the figures, FIG. 1 illustrates an assembly 100 according to embodiments of the present disclosure. Additionally, FIG. 2 illustrates a reactor system 200 comprising the assembly 100. In various embodiments, the assembly 100 is configured to level a susceptor 130.

In various embodiments, the assembly 100 comprises a susceptor leveling assembly 102, wherein the susceptor leveling assembly comprises a susceptor leveler plate 110 and a first positioning assembly 109(a). In various embodiments, the susceptor leveler plate 110 comprises one or more positioning areas (e.g., 103(a), 103(b), and 103(c)) configured to receive a leveling mechanism (e.g., a first leveling mechanism 104(a) of the first positioning assembly 109(a), a first leveling mechanism 104(b) of a second positioning assembly 109(b), and a first leveling mechanism 104(c) of a third positioning assembly 109(c)). The leveling mechanism can be or include, for example, a lever arm and a fulcrum, a wedge and the fulcrum, a gear ratio, a hydraulic press, any combination thereof, or any other simple machine. The susceptor leveling assembly 102 is illustrated with three positioning assemblies 109(a)-109(c), however, any suitable number of positioning assemblies could be used (e.g., one, two, three, four, etc.).

In various embodiments, the first positioning assembly 109(a) comprises the first leveling mechanism 104(a), which is in contact with the susceptor leveler plate 110, and a first positioning device 106(a). The first positioning assembly 109(a) is configured to adjust an angle of the susceptor leveler plate 110 in a first direction (e.g., a x-direction, a y-direction, or a z-direction) relative to a first plane (e.g., a xz plane, a zy plane, or a xy plane). In various embodiments, the first positioning device 106(a) can be in communication with a controller (e.g., a controller 205), which controls the first positioning device 106(a)'s movement to adjust the angle of the susceptor leveler plate 110 in the first direction.

In various embodiments, the first positioning assembly 109(a) further comprises a second positioning device 108(a), which can be in contact with the first leveling mechanism 104(a) or in contact with a second leveling mechanism that is also in contact with the susceptor leveler plate 110. The susceptor leveling assembly 102 is coupled to a pedestal 120, and the pedestal 120 is coupled to, and supports, a susceptor 130. The second positioning device 108(a) is also in communication with the controller and the controller is configured to control the second positioning device 108(a)'s movement to adjust the angle of the susceptor leveler plate 110 in a second direction (e.g., the x-direction, the y-direction, the z-direction). In various embodiments, the first direction is different than the second direction.

In various embodiments, the susceptor leveling assembly 102 comprises the second positioning assembly 109(b) and the third positioning assembly 109(c). Each positioning assembly can comprise a first leveling mechanism (e.g., the first leveling mechanisms 104(b), 104(c)), a first positioning device (e.g., the first positioning devices 106(b), 106(c)) and a second positioning device (e.g., the second positioning devices 108(b), 108(c)). In various embodiments, the second positioning assembly 109(b) and the third positioning assembly 109(c) are also in communication with the controller 205, and they are also operated in conjunction with the first positioning assembly 109(a) to control the angle of the susceptor 130.

Referring to FIG. 2, the reactor system 200 may comprise a reactor 230 comprising an upper body 1600 and a lower body 1300. The upper body 1600 and the lower body 1300 may be connected to each other. In more detail, the upper body 1600 and the lower body 1300 of a reactor may form reaction space 500 and lower space 1000 while face-contacting and face-sealing each other. The reactor 230 may include, in the reaction space 500 and lower space 1000, a substrate mounting unit 240, and a ring 800 surrounding the substrate mounting unit 240 and arranged between the substrate mounting unit 240 and the upper body 1600.

The reactor 230 may be configured to perform processing on an object to be processed, such as a substrate (e.g., a wafer). For example, the reactor 230 may be configured to perform heating, deposition, etching, cleaning, and/or other processing on the object to be processed. In some embodiments, the reactor 230 may be configured to perform a movement function, a vacuum sealing function, a heating function, an exhaust function, and/or other functions for the object to be processed such that the object is processed in the reactor. In an optional embodiment, the reactor 230 may be a reactor in which an atomic layer deposition (ALD) or a chemical vapor deposition (CVD) process or other deposition process is performed.

The upper body 1600 of the reactor may include a first gas inlet 225, a gas supply unit 210, an exhaust duct 600, and the ring 800. The lower body 1300 of the reactor may include a second gas inlet 900. The upper body 1600 and the substrate mounting unit 240 may form the reaction space 500. The lower body 1300 and the substrate mounting unit 240 may form the lower space 1000. A second gas generator 1900 may provide a second gas, and the second gas may be transmitted to the lower space 1000 through the second gas inlet 900.

The ring 800 may surround the substrate mounting unit 240 and may be arranged between the substrate mounting unit 240 and the upper body 1600. The ring 800 may generally have a circular ring shape, but is not limited thereto. For example, when the substrate mounting unit 240 has a quadrangular shape, the ring 800 may have a quadrangular ring shape. The ring 800 may be fixed to the upper body 1600. Alternatively, the ring 800 may be movably installed on the upper body 1600.

The substrate mounting unit 240 may comprise the susceptor 130 for supporting the substrate and a heater (not shown) for heating the substrate supported by the susceptor 130. The heater may be embedded within the susceptor 130. The substrate mounting unit 240 may further comprise the pedestal 120 to support the susceptor 130. For loading/unloading of the substrate, the substrate mounting unit 240 may be configured to be vertically movable.

A process gas introduced through the first gas inlet 225 may be supplied to the reaction space 500 and the substrate through the gas supply unit 210. The gas supply unit 210 may be a showerhead. A base of the showerhead may include a plurality of gas supply holes formed to eject the process gas (e.g., in a vertical direction toward the substrate). A process gas supplied on the substrate may undergo a chemical reaction with the substrate or a chemical reaction between gases, and then deposit a thin film or etch a thin film on the substrate. In the reaction space 500, a residual gas or un-reacted gas remaining after the chemical reaction with the substrate may be exhausted to the outside through an exhaust space 700 in an exhaust duct 600 and an exhaust pump (not shown). An exhaust method may be upper exhaust as illustrated and/or lower exhaust, whereby gas(es) are exhausted through the exhaust duct 600.

It may be desirable to keep substantially or about constant the distance between a lower surface of the gas supply unit 210 and an upper surface of the substrate on the susceptor 130. In other words, a distance between the susceptor 130 and the gas supply unit 210 at one end of the susceptor 130 is desirably about equal to a distance between the susceptor 130 and the gas supply unit 210 at the other end of the susceptor 130. Tilting and/or spacing adjustment may be performed during the process may be performed while the substrate is unloaded, for example, during an idle state. For example, during the idle state in a process, fine calibration of the susceptor 130 may be performed automatically. For example, by remotely controlling the controller 205 during the idle state or during substrate processing, fine calibration of the susceptor 130 may be performed without an operator entering the reactor system 200.

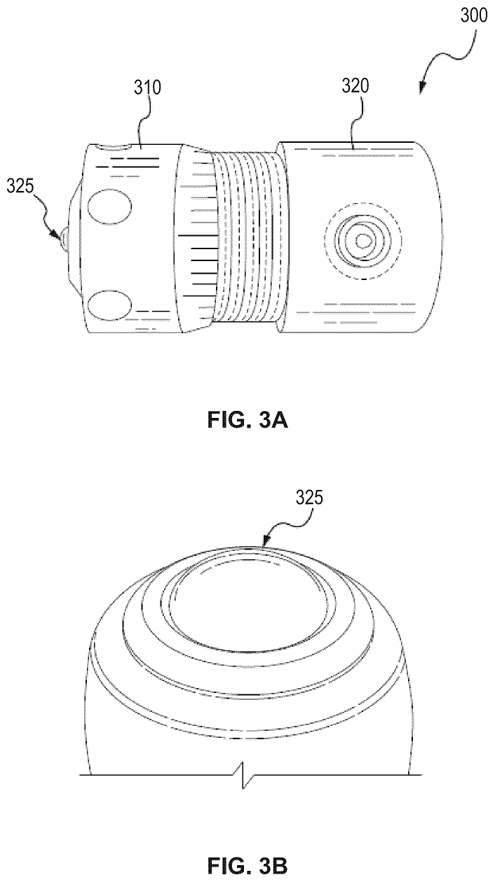

With additional reference to FIG. 3A and FIG. 3B, a positioning device 300 is shown. Positioning device 300 can be used as any of the positioning devices described herein (e.g., first positioning devices 106(a)-(c) and second positioning devices 108(a)-(c)). In various embodiments, the positioning device 300 may comprise a rotating body 310 and a fixed body 320. For example, the rotating body 310 may comprise a micrometer and may control a horizontal movement or vertical movement of the susceptor leveler plate 110 according to a rotational displacement and its corresponding scale position of the rotating body 310 with respect to the fixed body 320 against a leveling mechanism (e.g., the first leveling mechanism 104(a)). The fixed body 320 may be fixed to an adjustment mechanism frame (e.g., an adjustment mechanism frame 107), such that more than one positioning device 300 can be fixed to the adjustment mechanism frame (e.g., the first positioning device 106(a) and the second positioning device 108(a)). The rotating body 310 may be rotatable about a central axis of the fixed body 320. The adjustment mechanism may further comprise a ball bearing 325 within the rotating body 310 and disposed at the central axis.

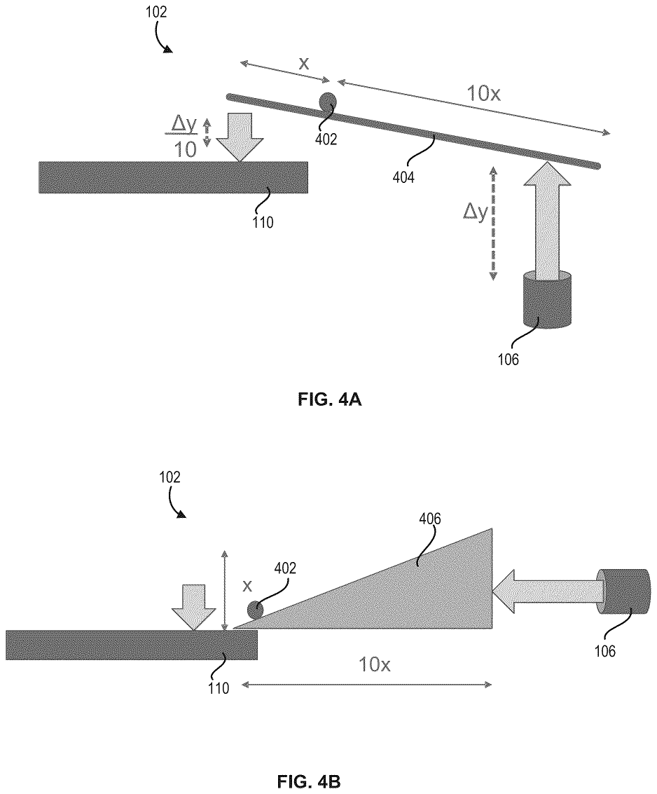

With reference to FIG. 4A and FIG. 4B, alternative arrangements of the susceptor leveling assembly 102 are illustrated. In FIG. 4A, an exemplary embodiment of the invention utilizes a lever arm system as the first leveling mechanism 104 (e.g., the first leveling mechanism 104(a)) to make more precise adjustments to the angle of the susceptor 130. For example, the first leveling mechanism 104 can be or include a fulcrum 402 and a lever arm 404. In various embodiments, a proximate end of the lever arm 404 is in contact with the susceptor leveler plate 110 and a distal end of the lever arm 404 is in contact with the positioning device 106. In the illustrated example, the positioning device 106 is configured to apply a force in the y-direction on the distal end of the lever arm 404. The fulcrum 402 is configured to be in contact with the lever arm 404 at a distance from the proximate end of the lever arm 404 of X and a distance from the distal end of the lever arm 404 of 10X. In various embodiments, the distance from the distal end of the lever arm is between about 5X and about 10X. The greater the distance from the distal end of the lever arm 404, the more precise the adjustments of the susceptor 130, because the positioning device 106 needs to move more distance than the susceptor leveler plate will move. For example, if the distance from the distal end of the lever arm 404 is 10X, and the positioning device 106 moves 3 centimeters in the positive y-direction, then the susceptor leveler plate 110 will move in the negative y-direction 3 millimeters.

In FIG. 4B, an exemplary embodiment of the invention utilizes a wedge system as the first leveling mechanism 104 (e.g., the first leveling mechanism 104(a)) to make more precise adjustments to the angle of the susceptor 130. For example, the first leveling mechanism 104 can be or include a fulcrum 402 and a wedge 406. In various embodiments, a proximate end of the wedge 406 is in contact with the susceptor leveler plate 110 and a distal end of the wedge 406 is in contact with the positioning device 106. The positioning device 106 is configured to apply a force in the x-direction on the distal end of the wedge 406. The fulcrum 402 is configured to be in contact with the wedge 406, and the wedge 406 is disposed between the susceptor leveler plate 110 and the fulcrum 402. In various embodiments, a height of the wedge 406 is X and a width of the wedge 406 is between about 5X and about 10X, or about 10X. The greater the width of the wedge 406 compared to the height of the wedge 406, the more precise the adjustments of the susceptor 130.

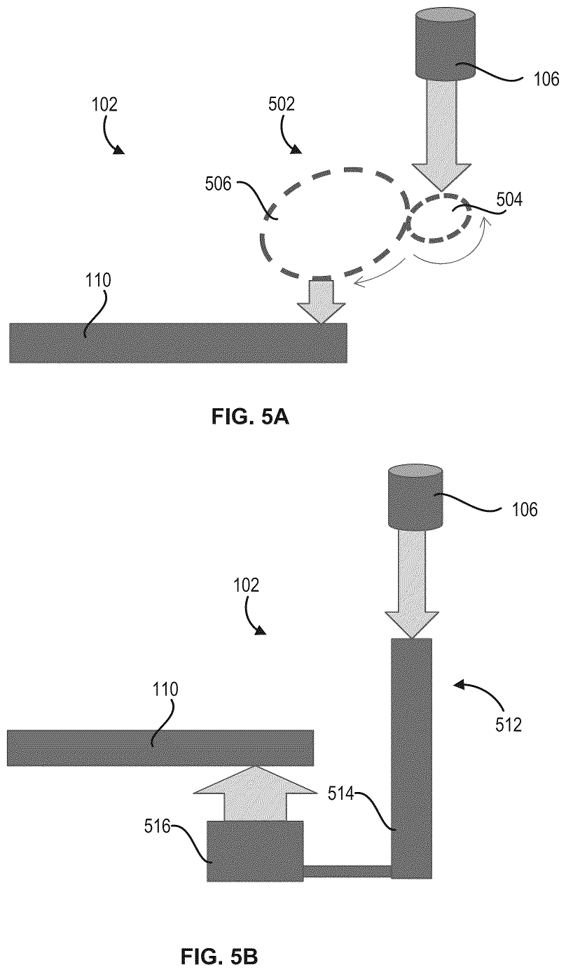

With further reference to FIG. 5A and FIG. 5B, alternative arrangements of the susceptor leveling assembly 102 are also shown. In FIG. 5A, an exemplary embodiment of the invention utilizes a gear system 502 as the first leveling mechanism 104 (e.g., the first leveling mechanism 104(a)) to make more precise adjustments to the angle of the susceptor 130. For example, the first leveling mechanism 104 can comprise a first gear 504 and a second gear 506, wherein the first gear 504 and the second gear 506 are in communication with each other. In various embodiments, the first gear 504 is in contact with the positioning device 106. The positioning device 106 is configured to apply a gear force on the first gear 504, which translates that force to the second gear 506. The second gear 506 is in contact with the susceptor leveler plate 110, and the second gear is configured to apply the gear force on the susceptor leveler plate 110. In various embodiments, a gear ratio between the second gear 506 and the first gear 504 is between about 5 and about 10. The greater the gear ratio, the more precise the adjustments of the susceptor 130, because the positioning device 106 needs to move further to adjust the susceptor leveler plate 110. For example, if the gear ratio is 10, and the positioning device 106 moves 3 centimeters, then the susceptor leveler plate 110 will move in the opposite direction 3 millimeters.

In FIG. 5B, an exemplary embodiment of the invention utilizes a hydraulic system 512 as the first leveling mechanism 104 (e.g., the first leveling mechanism 104(a)) to make more precise adjustments to the angle of the susceptor 130. For example, the first leveling mechanism 104 can comprise a first hydraulic piston 514 and a second hydraulic piston 516, wherein the first hydraulic piston 514 and the second hydraulic piston 516 are in communication with each other. In various embodiments, the first hydraulic piston 514 is in contact with the positioning device 106. The positioning device 106 is configured to apply a force on the first hydraulic piston 514, which translates that force to the second hydraulic piston 516. The second hydraulic piston 516 is in contact with the susceptor leveler plate 110, and the second gear is configured to apply the force on the susceptor leveler plate 110. In various embodiments, a hydraulic piston ratio (e.g., a ratio between the hydraulic volume of each piston) between the second hydraulic piston 516 and the first hydraulic piston 514 is between about 5 and about 10. The greater the gear ratio, the more precise the adjustments of the susceptor 130, because the positioning device 106 needs to move further to adjust the susceptor leveler plate 110. For example, if the hydraulic piston ratio is 10, and the positioning device 106 moves 3 centimeters, then the susceptor leveler plate 110 will move in the opposite direction 3 millimeters.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A susceptor leveling assembly, comprising:
a susceptor leveler plate;
a first positioning assembly, the first positioning assembly comprising:
a first positioning device, wherein the first positioning device is configured to move a pedestal in a vertical direction; and
a first leveling mechanism, wherein the first leveling mechanism is in contact with the first positioning device and the susceptor leveler plate,
wherein the first positioning assembly is configured to adjust an angle of the susceptor leveler plate in a first direction relative to a first plane.

2. The susceptor leveling assembly of claim 1, wherein the first positioning assembly comprises:
a second positioning device; and
a second leveling mechanism, wherein the second leveling mechanism is in contact with the second positioning device and the susceptor leveler plate,
wherein the second leveling mechanism is configured to adjust an angle of the susceptor leveler plate in a second direction relative to a second plane.

3. The susceptor leveling assembly of claim 2, wherein the first positioning device and the second positioning device are coupled to a first adjustment mechanism frame.

4. The susceptor leveling assembly of claim 3, wherein at least one of the first positioning device and the second positioning device comprise a micrometer.

5. The susceptor leveling assembly of claim 4, wherein the susceptor leveling assembly further comprises a controller in communication with the first positioning device and the second positioning device.

6. The susceptor leveling assembly of claim 5, wherein the controller is configured to control the first positioning device to adjust the angle of the susceptor leveler plate in the first direction and/or the second direction.

7. The susceptor leveling assembly of claim 1, wherein the first positioning assembly comprises a fulcrum, wherein the fulcrum is in contact with the first leveling mechanism and the fulcrum is disposed between a proximate end of the first leveling mechanism and a distal end of the first leveling mechanism.

8. The susceptor leveling assembly of claim 7, wherein the susceptor leveling assembly further comprises at least one of a second positioning assembly and a third positioning assembly.

9. An apparatus, comprising:
a pedestal; and
a susceptor leveling assembly, comprising:
a susceptor leveler plate coupled to the pedestal;
a first positioning assembly, the first positioning assembly comprising:
a first positioning device, wherein the first positioning device is configured to move the pedestal in a vertical direction; and
a first leveling mechanism, wherein the first leveling mechanism is in contact with the first positioning device and the susceptor leveler plate,
wherein the first positioning assembly is configured to adjust an angle of the susceptor leveler plate relative to a first plane.

10. The apparatus of claim 9, wherein the first positioning assembly comprises:
a second positioning device; and
a second leveling mechanism, wherein the second leveling mechanism is in contact with the second positioning device and the susceptor leveler plate, and
wherein the second leveling mechanism is configured to adjust an angle of the susceptor leveler plate relative to a second plane.

11. The apparatus of claim 10, wherein the first positioning device and the second positioning device are coupled to a first adjustment mechanism frame.

12. The apparatus of claim 11, wherein at least one of the first positioning device and the second positioning device comprise a micrometer.

13. The apparatus of claim 12, wherein the susceptor leveling assembly further comprises a controller in communication with the first positioning device and the second positioning device.

14. The apparatus of claim 13, wherein the controller is configured to control the first positioning device to adjust the angle of the susceptor leveler plate.

15. The apparatus of claim 9, wherein the first positioning assembly comprises a fulcrum, wherein the fulcrum is in contact with the first leveling mechanism and the fulcrum is disposed between a proximate end of the first leveling mechanism and a distal end of the first leveling mechanism.

16. The susceptor leveling assembly of claim 9, wherein the susceptor leveling assembly further comprises at least one of a second positioning assembly and a third positioning assembly.

17. A reactor system, comprising:
a susceptor;
a pedestal coupled to the susceptor; and
a susceptor leveling assembly, comprising:
a susceptor leveler plate coupled to the pedestal;
a first positioning assembly, the first positioning assembly comprising:
a first positioning device, wherein the first positioning device is configured to move the pedestal in a vertical direction; and
a first leveling mechanism, wherein the first leveling mechanism is in contact with the first positioning device and the susceptor leveler plate,
wherein the first positioning assembly is configured to adjust an angle of the susceptor leveler plate relative to a first plane.

18. The reactor system of claim 17, wherein the first positioning assembly further comprises:
a second positioning device; and
a second leveling mechanism, wherein the second leveling mechanism is in contact with the second positioning device and the susceptor leveler plate,
wherein the second leveling mechanism is configured to adjust an angle of the susceptor leveler plate in a second direction relative to a second plane.

19. The reactor system of claim 18, wherein the first positioning assembly comprises a fulcrum, wherein the fulcrum is in contact with the first leveling mechanism and the fulcrum is disposed between a proximate end of the first leveling mechanism and a distal end of the first leveling mechanism.

20. The reactor system of claim 19, wherein the first positioning device comprises a first micrometer.
